(19) United States
(12) Patent Application Publication
(10) Pub. No.: US 2008/0142885 A1
(43) Pub. Date: Jun. 19, 2008

(54) SEMICONDUCTOR DEVICE WITH IMPROVED SOURCE AND DRAIN AND METHOD OF MANUFACTURING THE SAME

(75) Inventor: Akira MINEJI, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 11/954,835

(22) Filed: Dec. 12, 2007

(30) Foreign Application Priority Data
Dec. 13, 2006 (JP) 2006-335570

(51) Int. Cl. H01L 29/78; H01L 21/336

(52) U.S. Cl. 257/344; 438/305; 257/E29.266; 257/E21.437

(57) ABSTRACT

A semiconductor device includes a gate, extension layers, source drain layers, and silicide layers. The gate is formed on one of a n-type semiconductor substrate and a n-type through a gate insulation film. The extension layers are p-type semiconductors and formed under sidewalls which are formed on both sides of the gate. The source drain layers are p-type semiconductors and formed in contact with the outsides of the extension layers. The silicide layers are formed on surface regions of the source drain layers. The extension layers include inhibitor elements which inhibit p-type impurity diffusion in the extension layers. The silicide layers do not substantially include the inhibitor elements.

### BACKGROUND OF THE INVENTION

1. Field of the Invention

The present invention relates to a semiconductor device and a method of manufacturing the same. The present invention particularly relates to a semiconductor device with improved source and drain and a method of manufacturing the same.

This Patent Application is based on Japanese Patent Application No. 2006-335570. The disclosure of the Japanese Patent Application is incorporated herein by reference.

2. Description of Related Art

With increasingly high integration of a LSI (Large-Scale Integrated Circuit), controlling an impurity profile of a source/drain diffusion layer of a CMOS (Complementary Metal-Oxide Semiconductor) is more important to transistor characteristics. In particular, it is necessary for a miniaturized transistor, to shallowly form a source/drain extension layer in order to inhibit short channel effect. At the same time, it is necessary to achieve reduction in resistance of a source/drain diffusion layer in order to prevent degradation of drive current.

Carbon (C) ion implantation is known to be effective as a method of inhibiting impurity diffusion in an extension layer of a p-type FET (Field-Effect Transistor) FIGS. 1A to 1D are sectional views showing a method of inhibiting impurity diffusion in an extension layer in a method of manufacturing a semiconductor device according to a related art.

First, as shown in FIG. 1A, a polysilicon gate 102 is provided on a semiconductor surface region between adjacent isolation sections 110 provided to an n-type silicon substrate (or well) 101 through a gate insulating film 103 made of silicon oxide. Next, as shown in FIG. 1B, extension layers 104 are formed by implanting ions containing carbon (C) and ions containing boron (B), using the gate 102 as a mask. Boron (B) is for a p-type impurity. Carbon (C) (inhibitor element) has an effect to inhibit boron (B) diffusion. Silicon (Si) and germanium (Ge) may be implanted in advance into regions where the extension layers 104 are formed, to amorphize the region.

Subsequently, as shown in FIG. 1C, sidewalls 105 in which silicon oxide film—silicon nitride film—silicon oxide film (SiOx—SiNx—SiOx) are laminated, are formed on the both sides of the gate 102 and the gate insulating film 103. Then, source/drain layers 106 are formed by implanting ions containing boron (B) for a p-type impurity into the extension layers 104 deeper than the extension layers 104, using the gate 102 and the sidewall 105 as a mask. The impurities (dopants) of the extension layers 104 and the source/drain layers 106 are activated thereafter, through heat treatment. After that, as shown in FIG. 1D, a nickel (Ni) film is formed over the entire surface followed by heat treatment, and nickel silicide (NiSi) layers 108 and 107 are formed at the upper parts of the source/drain layer 106 and the gate 102, respectively. An unnecessary metal film is removed thereafter. Nickel (Ni) has an effect to form a shallow silicide layer. In this way, a semiconductor device (a p-type FET (e.g. a p-type MOS transistor)) is formed.

As a related art, Japanese Laid-Open Patent Application JP-P2005-136351A (corresponding to U.S. patent application Ser. No. 10/800,749) discloses a semiconductor device and a method of manufacturing the semiconductor device. This semiconductor device includes a gate, a first impurity diffusion region, a third impurity diffusion region, and a second impurity diffusion region. The gate is formed on a semiconductor region through an insulating film. The first impurity diffusion region is formed in alignment with the gate in a surface layer of the semiconductor region. The third impurity diffusion region is formed separated from the gate in the surface layer. The second impurity diffusion region is formed in the surface layer, separated from the gate through the third impurity diffusion region and isolated from the first impurity diffusion region by the third impurity diffusion region. The third impurity diffusion region is characterized by containing diffusion inhibitor elements that inhibit diffusion of impurities in the second impurity diffusion region. The diffusion inhibitor elements may be at least one kind selected from germanium (Ge), nitrogen (N), fluorine (F), carbon (C), and indium (In), when impurities in the first and second impurity diffusion regions are p-type impurities.

The inventor of the present invention has now discovered the following concerning the related art illustrated in FIGS. 1A to 1D. Carbon exists in high concentrations in the vicinity of the surface of the silicon substrate where the nickel silicide layer 108 is formed. This carbon is considered to have an effect to stimulate nickel diffusion at the time of silicidation using nickel. For this reason, nickel is deeply diffused as a result of being affected by carbon to partly form a deeply-extended silicide layer 109 in some cases, even when the nickel silicide layer 108 is to be formed shallowly (thin film thickness) from the surface of the silicon substrate 101. The tip of the deeply-extended silicide layer 109 reaches near the border between the source/drain layer 106 and the silicon substrate 101 and even passes the border in some cases. Therefore, junction leakage may be increased, which has actually been confirmed by inventor's experiments.

It is desired to provide a technique capable of lowering resistance of a source/drain layer by forming a silicide layer on the source/drain layer without increasing junction leakage while maintaining a shallow extension layer to inhibit short channel effect, for such a miniaturized p-type FET as a p-type MOS transistor.

### SUMMARY

The present invention seeks to solve one or more of the above problems, or to improve upon those problems at least in part. In one embodiment, a semiconductor device includes: a gate configured to be formed on one of a n-type semiconductor substrate and a n-type through a gate insulation film; extension layers configured to be p-type semiconductors and formed under sidewalls which are formed on both sides of the gate; source drain layers configured to be p-type semiconductors and formed in contact with the outsides of the extension layers; and silicide layers configured to be formed on surface regions of the source drain layers, wherein the extension layers include inhibitor elements which inhibit p-type impurity diffusion in the extension layers, and the silicide layers do not substantially include the inhibitor elements.

In another embodiment, a method of manufacturing a semiconductor device, includes: forming extension layers by implanting ions containing inhibitor elements which inhibit p-type impurity diffusion and ions containing p-type impurities using a gate formed on one of a n-type semiconductor substrate and a n-type through a gate insulation film as a mask; forming source drain layers by implanting ions containing p-type impurities into the extension layers deeper than the extension layers using sidewalls which are formed on both sides of the gate as a mask; removing upper parts of the source drain layers using the gate and the sidewalls as a mask; and forming silicide layers in regions where the upper parts are removed.

In the present invention, the p-type extension layers include the inhibitor elements which inhibit p-type impurity diffusion. Due to the effect of the inhibitor elements, it is possible to shallowly form the extension layer. Therefore, it is possible to suppress the short channel effect. In addition, the silicide layers do not substantially include the inhibitor elements. Therefore, the case does not occur in which the inhibitor elements stimulate metal diffusion in the silicide layers. Consequently, it is possible to shallowly form the silicide layers. Hence, it is capable of lowering resistance of the source drain layers by forming the silicide layers on the source drain layers. In this case, shallowly forming the silicide layers makes it possible to separate the bottom surface of the silicide layers from the border between the source drain layers and the semiconductor substrate. As a result, junction leakage can be lowered.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A to 1D are sectional views showing a method of inhibiting impurity diffusion in an extension layer in a method of manufacturing a semiconductor device according to a related art;

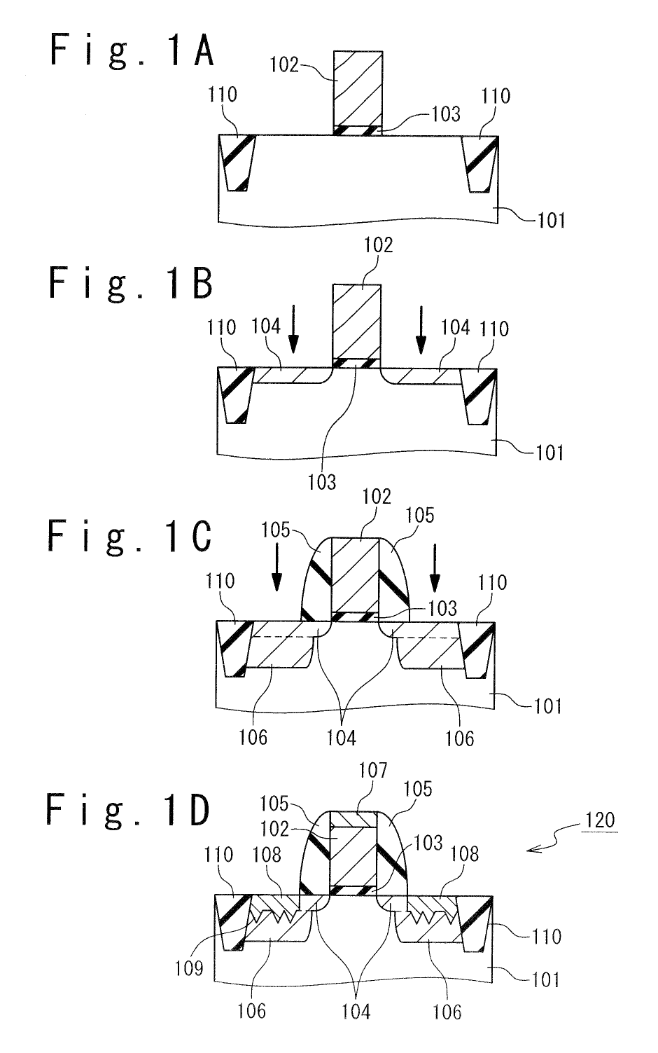

FIG. 2 is a sectional view showing a configuration of a first embodiment of a semiconductor device according to the present invention;

FIGS. 3A to 3C are sectional views showing a flow of a first embodiment of a method of manufacturing a semiconductor device according to the present invention;

FIGS. 4A to 4C are sectional views showing the flow of the first embodiment of the method of manufacturing a semiconductor device according to the present invention;

FIG. 5 is a graph showing examples of impurity concentration distributions of an extension layer in the semiconductor device in FIG. 2; and

FIG. 6 is a graph showing examples of impurity concentration distributions of a silicide layer and a source/drain layer in the semiconductor device in FIG. 2.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Embodiments of a semiconductor device and a method of manufacturing the semiconductor device according to the present invention will be explained below with reference to the attached drawings.

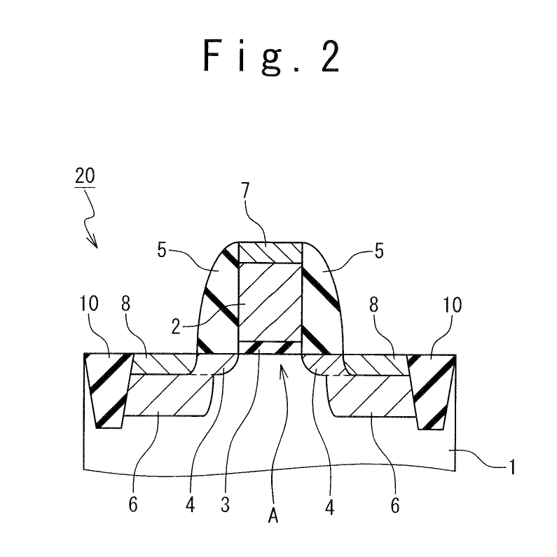

FIG. 2 is a sectional view showing a configuration of a first embodiment of a semiconductor device according to the present invention. A semiconductor device 20 is a p-type FET. Here, a p-type MOS transistor will be explained as an example of the semiconductor device 20. The semiconductor device 20 includes a semiconductor substrate (or well) 1, an isolation section 10, a gate insulating film 3, a gate 2, sidewalls 5, extension layers 4, source/drain layers 6, silicide layers 8 and 7.

When the semiconductor device 20 is the p-type MOS transistor, the semiconductor substrate (or a well, the same applies hereinafter) 1 is an n-type silicon (Si) substrate (or an n-type silicon (Si) well) for example. The p-type MOS transistor is provided in a region between the isolation sections 10 buried in the surface of the semiconductor substrate 1. The isolation section 10 is exemplified by silicon oxide (SiOx) of an STI (Shallow Trench Isolation) structure.

The gate insulating film 3 is provided in a surface region between the isolation sections 10 and on a channel region A of the p-type MOS transistor. The gate insulating film 3 is exemplified by silicon oxide (SiOx). The gate 2 is provided to cover the gate insulating film 3. The gate 2 is exemplified by polysilicon. The silicide layer 7 is provided to cover the gate 2. The silicide layer 7 is exemplified by nickel silicide (NiSi), platinum silicide (PtSi) and nickel platinum silicide (NiPtSi). The sidewall 5 is provided to cover the both sides of the gate 2, the gate insulating film 3, and the silicide layer 7. The sidewall 5 is exemplified by a laminated film of silicon oxide film—silicon nitride film—silicon oxide film (SiOx—SiNx—SiOx).

The extension layer 4 is a p-type impurity diffusion layer provided under the sidewalls 5 on a surface region of the semiconductor substrate 1. A p-type impurity is exemplified by boron (B). The extension layer 4 is formed shallowly compared with the source/drain layer 6. The extension layer 4 contains inhibitor elements that inhibit p-type impurity diffusion of in the extension layer 4. The inhibitor element is exemplified by carbon (C). The action of the inhibitor elements makes it possible to shallowly form the extension layer 4. By shallowly forming the extension layers 4 on the both sides of the channel region A, short channel effect can be inhibited. The extension layer 4 contains germanium (Ge) when germanium is used to amorphize a region where the extension layer 4 is to be formed at the time of manufacturing the semiconductor device 20 (mentioned later).

The source/drain layer 6 is a p-type impurity diffusion layer provided in contact with the outside of the extension layer 4 when seeing from the channel region A. A p-type impurity is exemplified by boron (B). The source/drain layer 6 is formed deeper than the extension layer 4. Deeply forming the source/drain layer 6 makes it possible to lengthen the distance between the bottom surface of the silicide layer 8 provided on the source/drain layer 6 and the bottom surface of the source/drain layer 6. Longer distance therebetween is preferable to reduce junction leakage. However, the depth of the source/drain layer 6 is limited in a given range on the ground of design and manufacturing.

The silicide layer 8 is a low resistance layer provided at a surface part of the source/drain layer 6. The upper surface of the silicide layer 8 is connected to a contact (not shown) that is connected to an upper interconnection layer (not shown). The silicide layer 8 is exemplified by nickel silicide (NiSi), platinum silicide (PtSi) and nickel platinum silicide (NiPtSi). The suicide layer 8 is formed shallowly to approximately the same extent as the extension layer 4. The depth (thickness) of the silicide layer 8 is mentioned later. Shallowly forming the silicide layer 8 makes it possible to separate the bottom surface of the silicide layer 8 from the border between the source/drain layer 6 and the semiconductor substrate 1. As a result, junction leakage can be lowered.

The silicide layer 8 is formed at a place where a portion to which the inhibitor elements are implanted in the surface region of the semiconductor substrate 1 is partly removed by etching and is backfilled with silicon (Si) epitaxial layer (mentioned later). For this reason, the silicide layer 8 contains much less the inhibitor elements than the extension layer 4 contains, or does not substantially contain the inhibitor elements as opposed to the extension layer 4. The silicide layer 8 includes germanium (Ge) when silicon germanium (SiGe) epitaxial layer is used for the above backfill (mentioned later). When a silicon (Si) or silicon germanium (SiGe) epitaxial layer that contains p-type impurities is used for the above backfill (mentioned later), the silicide layer 8 also contains the p-type impurities.

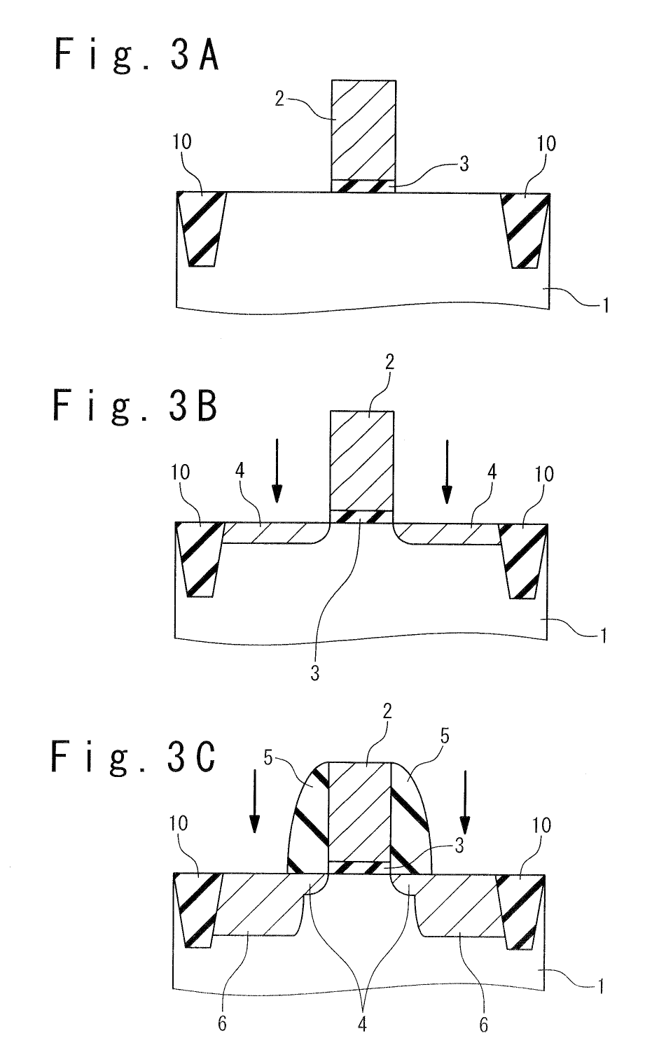

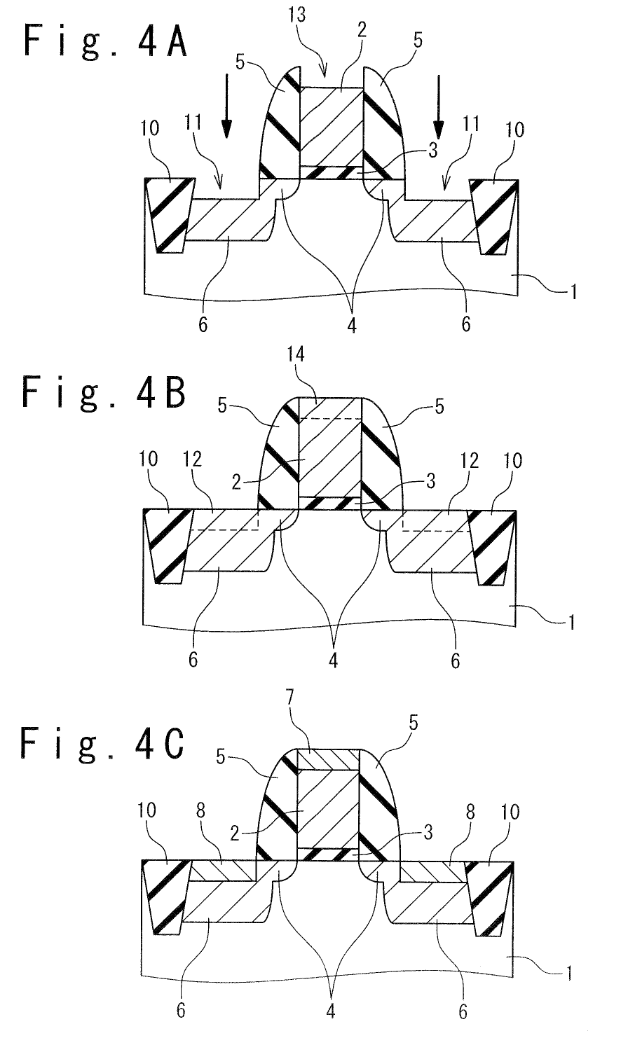

Next, a first embodiment of a method of manufacturing a semiconductor device according to the present invention will be described. FIGS. 3A to 3C and FIGS. 4A to 4C are sectional views showing an example of the first embodiment of the method of manufacturing a semiconductor device according to the present invention. A semiconductor device 20 is a p-type FET. Here, a p-type MOS transistor will be explained as an example of the semiconductor device 20.

As shown in FIG. 3A, an n-type silicon semiconductor substrate 1 is provided. The n-type impurity concentration is approximately 1×10¹⁸/cm³, for example. A silicon oxide isolation section 10 is formed at a given position of the semiconductor substrate 1. Then, a polysilicon gate 2 is formed on a surface region between the isolation sections 10 through a silicon oxide gate insulating film 3 (e.g. a thermally-oxidized film). A patterned polysilicon gate can be formed by using pattern formation of a photoresist film and dry etching process with the photoresist film as a mask, usually employed, after depositing polysilicon over the entire surface.

Next, as shown in FIG. 3B, ions containing germanium are implanted with a given depth into regions on the both sides of the gate 2 in the surface region of the semiconductor substrate 1, with the gate 2 as a mask. Implantation conditions are: Ge+(ion species), 1 to 10 keV (acceleration energy), and 5×10¹⁴ to 1×10¹⁵/cm² (dose amount), for example. Consequently, the regions where ions containing germanium have been implanted, are amorphized. Use of germanium makes it easy to form the amorphized regions extremely shallowly. As for an amorphized region, it is easy to implant p-type impurities such that the p-type impurities stay within the region. Therefore, it is possible to shallowly implant p-type impurities in a post process. Here, silicon can also be used instead of germanium. However, germanium is more preferable in that use of germanium can amorphize a shallower region with lower energy.

Subsequently, ions containing the inhibitor elements (carbon) that inhibit p-type impurity (boron) diffusion are implanted into the region into which ions containing germanium have been implanted. The depth of implantation is deeper than the depth at which ions containing germanium were implanted. However, that depth of implantation should be shallower than the source/drain layer 6. Implantation conditions are: C⁺ (ion species), 0.1 to 1 keV (acceleration energy), and 5×10¹⁴ to 1×10¹⁵/cm² (dose amount), for example. Consequently, the inhibitor elements are implanted into the amorphized region where ions containing germanium were implanted or a more deeply extended region that includes the amorphized region.

Furthermore, ions containing the p-type impurities (boron) are implanted into the amorphized region where ions containing germanium were implanted, to approximately the depth of the region. Implantation conditions are: BF₂⁺ (ion species), 1 to 10 keV (acceleration energy), and 5×10^{–}to 1×10¹⁵/cm² (dose amount), for example. Consequently, extension layers 4 are formed. Here, it is possible to reverse the order of the implantation of ions containing the inhibitor elements and the implantation of ions containing the p-type impurities, which is because the inhibitor elements inhibit diffusion of the p-type impurity at the time of activation annealing.

Next, as shown in FIG. 3C, sidewalls 5, which are laminated films of silicon oxide film—silicon nitride film—silicon oxide film, are formed to the both sides of the gate 2 and the gate insulating film 3. Then, with the gate 2 and the sidewall 5 as a mask, ions containing the p-type impurities (boron) are implanted into regions on the both sides of the gate 2 and the sidewalls 5 in the surface region of the semiconductor substrate 1, deeper than the depths of the extension layer 4 and the layer to which the inhibitor elements are implanted. Implantation conditions are: BF₂⁺ (ion species), 5 to 20 keV (acceleration energy), and 5×10¹⁴ to 1×10¹⁵/cm² (dose amount), for example. Consequently, the source/drain layers 6 are formed. Ions in the extension layers 4 and the source/drain layers 6 are activated thereafter, through heat treatment.

At the above heat treatment, the extension layer 4 contains the inhibitor elements (carbon) that inhibit the p-type impurity (boron) diffusion. Therefore, the p-type impurities are inhibited from diffusing from the region into which the p-type impurities are implanted. As a result, the extension layer 4 can be kept shallow even after activation annealing.

After that, as shown in FIG. 4A, regions that contain plenty of the inhibitor elements (carbon) in the upper parts of the source/drain layers 6 are removed by such a method as etch back using the gate 2 and the sidewalls 5 as a mask. As a result of the removal, concave portions 11 are formed at the upper parts of the source/drain layers 6. At this time, a region in the upper part of the gate 2 is etched back at the same time to form a concave portion 13.

Next, as shown in FIG. 4B, epitaxial layers 12 and 14 where silicon is selectively grown epitaxially, are formed at the concave portions 11 and 13 respectively, by a method exemplified by a CVD method. As an example of an epitaxial growth method, silicon is epitaxially grown on silicon of the respective concave portions by introducing a silane gas (SiH₄) or disilane gas (Si₂H₆) and an H₂ gas at respective given flow rates into a vacuum chamber set at given temperature and pressure. At this time, a chlorine (Cl) or hydrogen chloride (HCl) gas is flown to inhibit nucleus generation on silicon oxide or silicon nitride. Germane gas (GeH₄) is also introduced in addition to a silane gas and so forth, when silicon germanium is epitaxially grown. It is preferable because of the relation with other processes, that the heights (thicknesses) of the epitaxial layers 12 should be set such that the upper surfaces thereof are approximately level with the original surface of the semiconductor substrate 1. Similarly, it is preferable because of the relation with other processes, that the height (thickness) of the epitaxial layer 14 should be set such that the upper surface thereof is approximately level with the height of the sidewall.

The epitaxial layer 12 may contain germanium in the order of several tens of percent for example. By providing silicon germanium on the upper part of the source/drain layer 6, stress on a channel region between the adjacent extension layers 4 is increased. As a result, carrier mobility in the channel region is improved. That is, transistor characteristics of the semiconductor device 20 can be more improved.

Additionally, the epitaxial layer 12 may contain p-type impurities (boron). When the epitaxial layer 12 does not contain the p-type impurities, the epitaxial layer 12 has high resistance. Therefore, it is necessary in order to achieve fine connection (low resistance) between a silicide layer 8 formed in the epitaxial layer 12 and the source/drain layer 6, to make the silicide layer 8 and the source/drain layer 6 directly come in contact with each other by thickening the silicide layer 8. When the epitaxial layer 12 contains the p-type impurities however, the epitaxial layer 12 of low resistance to which the p-type impurities are doped, fills the space between the silicide layer 8 and the source/drain layer 6 even when the silicide layer 8 is thin and the silicide layer 8 and the source/drain layer 6 do not directly come in contact with each other, making it possible to connect the both with low resistance. That is to say, it is more preferable to provide the epitaxial layer 12 with p-type impurities, which increases the flexibility in the thickness of the silicide layer 8.

After that, as shown in FIG. 4C, a metal film (nickel) is formed over the entire surface followed by heat treatment and silicide layers 8 and 7 (nickel silicide) are formed on the upper parts of the source/drain layers 6 and the gate 2, respectively. An unnecessary metal film is removed thereafter. It is possible at this heat treatment as well, to prevent the p-type impurities from unnecessarily diffusing, since the extension layer 4 contains the inhibitor elements that inhibit the p-type impurity diffusion. As a result, it is possible to keep the extension layer 4 shallow. In this way, the p-type FET (p-type MOS transistor) is formed.

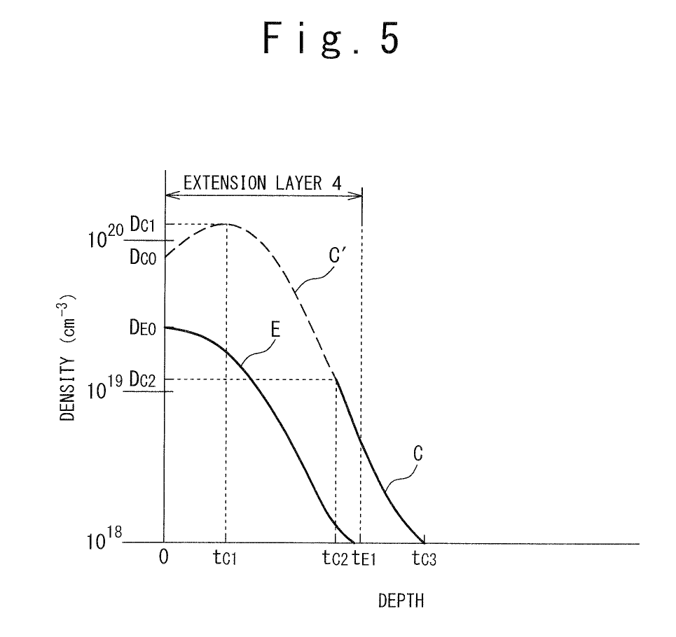

FIG. 5 is a graph showing examples of impurity concentration distributions of the extension layer in the semiconductor device of FIG. 2. The vertical axis and horizontal axis show a concentration and a depth from the surface of the semiconductor substrate 1, respectively.

In this example, the inhibitor element (carbon) concentration distribution in the extension layer 4 is indicated by a curved line C′ (broken line) and a curved line C (solid line). The surface concentration D_{C0} is approximately 9×10¹⁹/cm³. At the depth t_{C1}, the peak concentration D_{C1} is approximately 2×10²⁰/cm³. At the depth t_{C2}, the concentration D_{C1} is approximately 2×10¹⁹/cm³, which is approximately 1/10 of the peak concentration D_{C1}. At the depth t_{C3}, the concentration is approximately 1×10¹⁸/cm³, which is approximately 1/100 of the peak concentration D_{C1}.

On the other hand, the p-type impurity (boron) concentration distribution in the extension layer 4 is indicated by a curved line E (solid line). The peak concentration D_{E0} is approximately 4×10¹⁹/cm³ at the surface. At the depth t_{E1}, the concentration is approximately 1×10¹⁸/cm³.

Here, the depth of the extension layer 4 is defined such that the p-type impurity concentration of the extension layer 4 and the n-type impurity concentration of the semiconductor substrate 1 (approximately 1×10¹⁸/cm³) are equal. In this case, the depth of the extension layer 4 is t_{E1}.

As shown in FIG. 5, in the extension layer 4, the inhibitor element concentration (the curved line C′ and the curved line C) is sufficiently high compared with the p-type impurity concentration of (the curved line E) throughout the depth of the extension layer 4. Therefore, it is possible to shallowly generate and maintain the extension layer 4 without unnecessary p-type impurity diffusion, due to the effect of the inhibitor element.

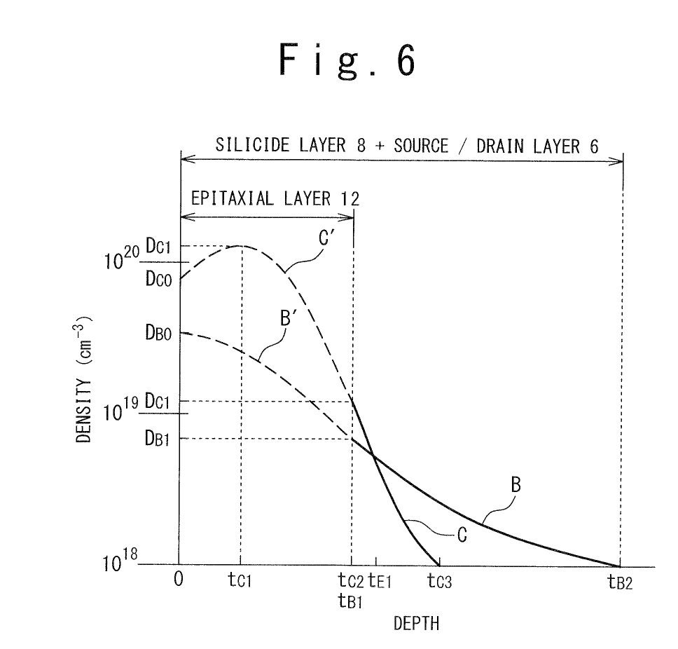

FIG. 6 is a graph showing examples of impurity concentration distributions of the silicide layer and the source/drain layer in the semiconductor device in FIG. 2. The vertical axis and horizontal axis show a concentration and a depth from the surface of the semiconductor substrate 1, respectively.

An inhibitor element (carbon) concentration distribution in the source/drain layer 6 is indicated by a curved line C (solid line). The upper part of the source/drain layer 6 is once removed by etch back and the epitaxial layer 12 is formed thereon. Therefore, the region (epitaxial layer 12) does not substantially contain an inhibitor element (carbon), resulting in the concentration being substantially zero (0). This graph shows a case where the epitaxial layer 12 is formed after etch back is performed up to the depth t_{C2}. Therefore, the concentration is substantially zero (0) before reaching the depth t_{C2}. At the depth t_{C2}, peak concentration D_{C1} is approximately 10¹⁹/cm³. At the depth t_{C3}, concentration is approximately 1×10¹⁸/cm³.

A p-type impurity (boron) concentration distribution in the source/drain layer 6 is indicated by a curved line B (solid line). As mentioned above, the upper part of the source/drain layer 6 is once removed by etch back and the epitaxial layer 12 is formed thereon. When the epitaxial layer 12 is an intrinsic semiconductor therefore, the p-type impurities are not contained and the concentration is substantially zero (0). This graph shows a case where the epitaxial layer 12 (intrinsic semiconductor) is formed after etch back is performed up to the depth t_{B1} (=t_{C2}). Therefore, the concentration is substantially zero (0) before reaching the depth t_{B1}. At the depth t_{B1}, the peak concentration D_{B1}, is approximately 10¹⁹/cm³. At the depth t_{B2}, the concentration is approximately 1×10¹⁸/cm³.

Here, the depth of the source/drain layer 6 is defined such that the p-type impurity concentration of the source/drain layer 6 and the n-type impurity concentration of the semiconductor substrate 1 (approximately 1×10¹⁸/cm³) are equal. In this case, the depth of the source/drain layer 6 is t_{B2}.

As shown in FIG. 6, an inhibitor element is not present in the epitaxial layer 12 in the upper part of the source/drain layer 6 (from the surface to the depth t_{B1}). Therefore, nickel in the silicide layer 8 formed in the epitaxial layer 12 is not affected at all by the inhibitor element. From a standpoint of the depth direction in the source/drain layer 6, the peak concentration of the inhibitor element concentration (the curved line C) is 1/10 or less than the peak concentration of the original inhibitor element concentration (the same curved lines C′ and C as the extension layer 4) Thus study by the inventor of the present invention has revealed that inhibitor elements of such a low concentration do not have a bad effect on nickel in the silicide layer 8 that comes into contact with the inhibitor elements. That is to say, nickel in the silicide layer 8 is prevented from being abnormally diffused in the source/drain layer 6. As a result, the silicide layer 8 can be kept shallow, thereby inhibiting junction leakage. Thus it is preferable that the epitaxial layer 12 should be formed with a depth where a concentration of the inhibitor element at least is 1/10 or less than the peak concentration.

Since the epitaxial layer 12 is an intrinsic semiconductor in this case, the silicide layer 8 needs to reach at least the depth t_{B1} (=t_{C2}). If the silicide layer 8 does not reach the depth t_{B1} (=t_{C2}), an electrically high resistance layer of an intrinsic semiconductor is put between the bottom surface of the silicide layer 8 and the depth t_{B1} (=t_{C2}). However, the silicide layer 8 does not need to reach the depth t_{B1} (=t_{C2}) when the epitaxial layer newly formed is a p-type semiconductor to which p-type impurities are doped in high concentration. This is because a layer between the bottom surface of the silicide layer 8 and the depth t_{B1} (=t_{C2}) is a highly-concentrated p-type semiconductor, which has electrically low resistance, even when the silicide layer 8 does not reach the depth t_{B1} (=t_{C2}). That is, the epitaxial layer 12 is more preferably a p-type semiconductor to which p-type impurities are doped in high concentration, in that the flexibility in the thickness of the silicide layer 8 can be increased.

According to the present invention, it is possible in a p-type FET, to lower resistance of a source/drain layer by forming a silicide layer on the source/drain layer with junction leakage being inhibited while maintaining a shallow extension layer to inhibit short channel effect.

It is obvious that the present invention is not limited to the above embodiments and the embodiments can appropriately be modified or changed within the scope of technical ideas of the invention.

According to the present invention, a technique is provided which is capable of lowering resistance of a source/drain layer by forming a silicide layer on the source/drain layer without increasing junction leakage while maintaining a shallow extension layer to inhibit short channel effect, for a p-type FET.

It is apparent that the present invention is not limited to the above embodiment, but may be modified and changed without departing from the scope and spirit of the invention.

What is claimed is:

1. A semiconductor device comprising:
a gate configured to be formed on one of a n-type semiconductor substrate and a n-type through a gate insulation film;
extension layers configured to be p-type semiconductors and formed under sidewalls which are formed on both sides of said gate;
source drain layers configured to be p-type semiconductors and formed in contact with the outsides of said extension layers; and
silicide layers configured to be formed on surface regions of said source drain layers,
wherein said extension layers include inhibitor elements which inhibit p-type impurity diffusion in said extension layers, and
said silicide layers do not substantially include said inhibitor elements.

2. The semiconductor device according to claim 1, wherein said inhibitor elements includes carbon.

3. The semiconductor device according to claim 1, wherein said silicide layers includes at least one of nickel and platinum.

4. The semiconductor device according to claim 1, wherein said silicide layers includes germanium.

5. The semiconductor device according to claim 1, wherein said silicide layers includes p-type impurities.

6. The semiconductor device according to claim 2, wherein said silicide layers includes at least one of nickel and platinum.

7. The semiconductor device according to claim 2, wherein said silicide layers includes germanium.

8. The semiconductor device according to claim 2, wherein said silicide layers includes p-type impurities.

9. The semiconductor device according to claim 6, wherein said silicide layers includes germanium.

10. The semiconductor device according to claim 6, wherein said silicide layers includes p-type impurities.

11. A method of manufacturing a semiconductor device, comprising:
forming extension layers by implanting ions containing inhibitor elements which inhibit p-type impurity diffusion and ions containing p-type impurities using a gate formed on one of a n-type semiconductor substrate and a n-type through a gate insulation film as a mask;
forming source drain layers by implanting ions containing p-type impurities into said extension layers deeper than said extension layers using sidewalls which are formed on both sides of said gate as a mask;
removing upper parts of said source drain layers using said gate and said sidewalls as a mask; and
forming silicide layers in regions where said upper parts are removed.

12. The method of manufacturing a semiconductor device according to claim 11, wherein said inhibitor elements includes carbon.

13. The method of manufacturing a semiconductor device according to claim 11, wherein said forming silicide layers step includes:
forming epitaxial layers in said regions where said upper parts are removed, and
forming said silicide layers by silicidation of said epitaxial layers.

14. The method of manufacturing a semiconductor device according to claim 13, wherein said epitaxial layers include germanium.

15. The method of manufacturing a semiconductor device according to claim 13, wherein said epitaxial layers include p-type impurities.

16. The method of manufacturing a semiconductor device according to claim 11, wherein said silicide layers include at least one of nickel and platinum.

17. The method of manufacturing a semiconductor device according to claim 12, wherein said forming silicide layers step includes:
forming epitaxial layers in said regions where said upper parts are removed, and
forming said silicide layers by silicidation of said epitaxial layers.

18. The method of manufacturing a semiconductor device according to claim 17, wherein said epitaxial layers include germanium.

19. The method of manufacturing a semiconductor device according to claim 17, wherein said epitaxial layers include p-type impurities.

20. The method of manufacturing a semiconductor device according to claim 12, wherein said silicide layers include at least one of nickel and platinum.
